(19) United States
(12) Patent Application Publication
(10) Pub. No.: US 2026/0142133 A1
(43) Pub. Date: May 21, 2026

(54) DRY ETCHING DEVICE AND METHOD

(71) Applicant: BEIJING GOLDENPOWER ELECTRONIC TECHNOLOGY CO., LTD., Beijing (CN)

(72) Inventor: Guohao Gao, Beijing (CN)

(21) Appl. No.: 18/992,586

(22) PCT Filed: Sep. 27, 2023
(86) PCT No.: PCT/CN2023/121891

§ 371 Date: Jan. 9, 2025

(30) Foreign Application Priority Data
Sep. 28, 2022 (CN) 202211202559.3

(51) Int. Cl. H01J 37/32

(52) U.S. Cl. CPC H01J 37/32623; H01J 37/32449; H01J 37/32467; H01J 37/32477; H01J 37/32522; H01J 37/32715; H01J 37/32834; H01J 2237/0213; H01J 2237/1825; H01J 2237/20214; H01J 2237/24585; H01J 2237/3341

(57) ABSTRACT

Embodiments of the present application provide a dry etching device and method. The dry etching device includes a vacuum reaction chamber, a workpiece disc driven by a rotating assembly and a plasma excitation source emitting plasma to an etching area are provided in the vacuum reaction chamber, the etching area covers the axis of the workpiece disc and is located on one side of the axis; and a plasma density correction system is arranged between the plasma excitation source and the etching area.

### CROSS-REFERENCE TO RELATED APPLICATION

The present disclosure claims priority to Chinese patent Application No. 202211202559.3, filed with the Chinese Patent Office on Sep. 28, 2022, entitled “DRY ETCHING DEVICE AND METHOD”, the entire contents of which are incorporated herein by reference.

### TECHNICAL FIELD

The present disclosure relates to the field of etching, and specifically to a dry etching device and a method.

### BACKGROUND ART

The dry etching is a technique for etching thin films by the plasma. When the gas exists in the form of plasma, the chemical activity of gas-active free radicals in the plasma is much stronger than that of the normal-state gas. The suitable gas is selected according to different etched materials, so as to react faster with the material, and thereby realize the purpose of etching removal. It can further guide and accelerate the plasma by using the electric field, so that it has a certain energy. When it bombards the surface of the etched material, atoms of the etched material will be hit out, so as to realize the etching by using the physical energy transfer.

In the prior reactive ion etching RIE device, after the etching area increases (with a diameter of 500 mm or more), the etching gas will have problems of the uneven distribution, and the poor stability and consistency, so that it is difficult to realize the uniform etching transfer of a micro-nanostructured graphic with a large area. In the large chamber, the etching residual reaction gas remains in the etching area due to the delay effect of the gas diffusion, so that it is difficult to form dynamically balanced uniform gas components with the large area, which results in a large difference in etching rates between the edge and the center of the substrate. Therefore, it helps to realize the uniform etching of the substrate by reducing the volume of the etching device chamber.

For the large-sized workpiece, an etching device exists in the prior art that performs the partitioned etching on the workpiece when the plasma excitation source moves relative to the workpiece, but the device also has the following problems. If the plasma excitation source is fixed and the workpiece moves, the volume of the etching chamber is required to be relatively large, and the coverage area of the etching chamber is at least twice that of the workpiece; and if the workpiece does not move and the plasma excitation source moves, it further needs to ensure the sealing of the etching chamber during the movement process since the components of the plasma excitation source are relatively complex, which increases the processing difficulty of the etching device and improves the processing cost.

In view of this, the present disclosure is proposed.

### SUMMARY

The objective of the present disclosure includes, for example, providing a dry etching device and a method, which can reduce the volume of the etching device, and particularly facilitate the processing of some large-sized workpieces.

The embodiments of the present disclosure can be realized in the following ways.

In a first aspect, the present disclosure provides a dry etching device including a vacuum reaction chamber, wherein the vacuum reaction chamber is provided with a workpiece disc driven by a rotating assembly, an etching area, and a plasma excitation source emitting plasma to the etching area, wherein the etching area covers an axis center of the workpiece disc and is located on one side of the axis center, and a plasma density correction system is arranged between the plasma excitation source and the etching area.

In an optional embodiment, the plasma density correction system includes a correction grid and a movement assembly driving the correction grid to rotate and move;
preferably, a mesh coverage rate of the correction grid gradually reduces in a direction away from an axis of the workpiece disc;
preferably, an angle between the correction grid and the workpiece disc is 0˜75°; and
preferably, the correction grid is made of a metal material or polymer material.

In an optional embodiment, a pressure monitoring device and a vacuum acquiring device are arranged in the vacuum reaction chamber;
preferably, a pressure controller for controlling opened size of a valve of the vacuum acquiring device according to a pressure monitored by the pressure monitoring device is further provided;
preferably, the pressure controller is a PID controller; and
preferably, more than four vacuum acquiring devices are provided, and the more than four vacuum acquiring devices are evenly distributed around the plasma excitation source.

In an optional embodiment, a tail gas treatment device is connected to a gas outlet of the vacuum pump, wherein a filter is arranged in the tail gas treatment device, and an anti-corrosion coating layer is arranged at a position where the filter is in contact with the tail gas; and
preferably, the anti-corrosion coating layer is a polytetrafluoroethylene coating layer.

In an optional embodiment, a temperature monitoring device and a heat exchanger are arranged in the vacuum reaction chamber;
preferably, a temperature controller for controlling switching of the heat exchanger according to a temperature monitored by the temperature monitoring device is further provided; and
   preferably, the temperature controller is the PID controller.

In an optional embodiment, the plasma excitation source is provided with a mobile assembly that can drive the plasma excitation source to move in X, Y, and Z directions;
components in contact with an etching gas or the plasma in the plasma excitation source are all made of duplex stainless steel; and
a distance between the plasma excitation source and the etching area in a Z-axis direction is between 20˜100 cm.

In an optional embodiment, the rotating assembly includes a motor, a rotating shaft connected to a power output shaft of the motor, and the workpiece disc is mounted on the rotating shaft; and
preferably, the motor is located in the vacuum reaction chamber, wherein the vacuum reaction chamber is provided with an avoidance hole for the rotating shaft to penetrate, and a sealing structure is arranged between the avoidance hole and the rotating shaft.

In an optional embodiment, a blowing device is further included, wherein the blowing device includes a gas source, a gas pipe connected to the gas source, and a blowing port connected to the gas pipe, wherein the blowing port is arranged towards the workpiece disc.

In a second aspect, the present disclosure provides a dry etching method utilizing the device of the foregoing embodiments, including: placing a substrate to be etched on the workpiece disc; driving the workpiece disc; charging an etching gas; starting a plasma excitation source; performing an etching micro-nano processing on the substrate; and correcting a density of the plasma emitted by the plasma excitation source by adjusting the plasma density correction system before or during the etching.

In an optional embodiment, after starting the plasma excitation source, a power of the plasma excitation source is gradually increased to a specified range after the gas pressure and a glow of the plasma are stabilized, so as to perform the etching micro-nano processing for the substrate;
preferably, before charging the etching gas, an inert gas is first charged to replace a flowing atmosphere in the vacuum reaction chamber, and the inert gas is stopped charging after the replacement is completed;
a pressure of the vacuum reaction chamber is 3×10⁻²˜3×10⁻¹ Pa;
preferably, a temperature inside the vacuum reaction chamber is 80-120° C.;
preferably, a rotation speed of the workpiece disc is 0˜50 r/min; and
preferably, the blowing device is turned on after the etching is completed, and a flow rate of a blowing gas is 0˜1 scm/h.

The embodiments of the present disclosure include the flowing beneficial effects.

By rotating the workpiece disc when etching, the workpiece rotates around the circle center of the workpiece disc, so that the position on the workpiece sequentially passes through the etching area for etching. The etching area in the embodiment does not need to cover the entire workpiece, and the partitioned etching can be performed on the workpiece by only covering a part of the workpiece. Compared with the traditional dry etching system, it can greatly reduce the volume of the device, and especially for the large-sized workpiece, it can significantly reduce the volume of the device. Meanwhile, the device and method of the present disclosure can also be used for processing the small-diameter workpiece, so as to be used in a wider range.

In the present disclosure, the workpiece rotating into the etching area is etched by utilizing the uniform area of the plasma excitation source. For the workpiece, the duration per unit area passing through the uniform area of the ion source reduces with the increase of the distance from the axis of the workpiece disc, which causes uneven etching of the workpiece. Therefore, a plasma density correction system is arranged between the plasma excitation source and the etching area. It can simultaneously correct the plasma density of the plasma excitation source and plasma densities of the rotating workpiece at different positions, so as to regulate the etching evenness of the large-sized substrate.

### BRIEF DESCRIPTION OF DRAWINGS

In order to more clearly illustrate the technical solutions of the examples of the present disclosure, the drawings to be used in the examples will be briefly introduced below. It should be understood that the following drawings only show certain examples of the present disclosure, and therefore should not be regarded as a limitation of the scope. Other relevant drawings can be obtained from these drawings by a person of ordinary skill in the art without inventive efforts.

FIG. 1 shows a structure schematic diagram of the dry etching device in the present disclosure.

### REFERENCE NUMBERS

100—dry etching device; 110—vacuum reaction chamber; 120—workpiece disc; 121—rotating assembly; 130—plasma excitation source; 131—gas storage tank; 140—correction grid; 150—pressure monitoring device; 151—vacuum acquiring device; 152—tail gas treatment device; 160—temperature monitoring device; 161—heat exchanger; and 170—blowing device.

### DETAILED DESCRIPTION OF EMBODIMENTS

In order to make the purpose, technical solutions, and advantages of the examples of the present disclosure clearer, the technical solutions in the examples of the present disclosure will be described clearly and completely below in conjunction with drawings in the embodiments of the present disclosure. It is obvious that the embodiments described are partial embodiments of the present disclosure and not all of them. The components of embodiments of the present disclosure generally described and shown in the drawings herein can be arranged and designed in various different configurations.

Accordingly, the detailed description of embodiments of the present disclosure provided in the drawings below is not intended to limit the scope of the present disclosure for which protection is claimed, but only represents selected examples of the present disclosure. Based on the embodiments in the present disclosure, all other embodiments obtained by a person of ordinary skill in the art without inventive efforts all fall within the scope of protection of the present disclosure.

It should be noted that similar symbols and letters denote similar items in the following drawings, so that once an item is defined in a drawing, no further definition or explanation of it is required in the subsequent drawings.

In the description of the present disclosure, it should be noted that the orientation or position relationship indicated by the terms, “up”, “down”, “inside”, “outside”, etc., is the orientation or position relationship based on the drawings, or is the orientation or position relationship of the product of the present disclosure customarily placed in use, which are only to facilitate the description of the present disclosure and simplify the description, and are not to indicate or imply that the device or element referred to must have a particular orientation, or be constructed and operated with a particular orientation, and therefore cannot to be understood as limitations of the present disclosure.

Additionally, the terms “first”, and “second”, etc., are used only to differentiate the description, and are not to be understood as indicating or implying relative importance.

It is noted that features in embodiments of the present disclosure can be combined with each other without conflict.

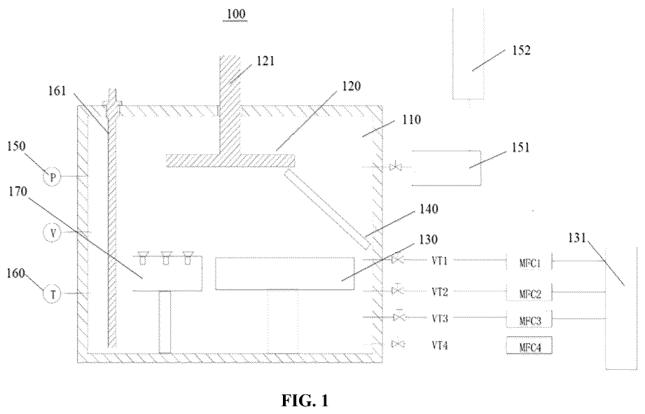

Referring to FIG. 1, the embodiment provides a dry etching device 100 including a vacuum reaction chamber 110, wherein the vacuum reaction chamber 110 is provided with a workpiece disc 120 driven by a rotating assembly 121, an etching area, and a plasma excitation source 130 emitting plasma to the etching area, wherein the etching area covers an axis center of the workpiece disc 120 and is located on one side of the axis center, and a plasma density correction system is arranged between the plasma excitation source 130 and the etching area.

When using the dry etching device 100 provided by the embodiment, the positions of the workpiece disc 120 and the plasma excitation source 130 are adjusted first, and then the plasma density correction system is adjusted, so as to adjust the density of the plasma emitted by the plasma excitation source 130. After the device is adjusted, the workpiece is fixed to the workpiece disc 120, and then the plasma excitation source 130 is turned on for etching.

The workpiece is mounted at the position of the circle center of the workpiece disc 120. By rotating the workpiece disc 120 when etching, the workpiece rotates around the circle center of the workpiece disc 120, so that the position on the workpiece sequentially passes through the etching area for etching. The etching area in the embodiment does not need to cover the entire workpiece, and the partitioned etching can be performed on the workpiece by only covering a part of the workpiece. Compared with the traditional dry etching system, it can greatly reduce the volume of the device.

The plasma generated by the plasma excitation source 130 can be regarded as uniform within a certain range, and in the embodiment, the workpiece rotating into the etching area is etched by utilizing the uniform area of the plasma excitation source 130. For the workpiece, the duration per unit area passing through the uniform area of the ion source reduces with the increase of the distance from the axis of the workpiece disc 120, which causes uneven etching of the workpiece. Therefore, a plasma density correction system is arranged between the plasma excitation source 130 and the etching area.

Further, the plasma density correction system includes a correction grid 140 and a movement assembly driving the correction grid 140 to rotate and move.

Preferably, a mesh coverage rate of the correction grid 140 gradually reduces in a direction away from an axis of the workpiece disc 120.

Preferably, an angle between the correction grid 140 and the workpiece disc 120 is 0˜75°.

Preferably, the correction grid 140 is made of a metal material or polymer material.

The plasma density correction system in the embodiment includes the correction grid 140, and the correction grid 140 is provided with meshes. The plasma can be intercepted when hitting on the correction grid 140, and it can continue to move forward to the etching area for etching the workpiece through the meshes. By adjusting the size and arrangement of the meshes, the density of plasma passing through the correction grid 140 can be adjusted. In order to effectively intercept the plasma, the correction grid 140 is preferably made of the metal material or polymer material, and preferably the stainless-steel material.

The running trajectory of the plasma generated by the plasma excitation source 130 is adjusted. The correction grid 140 is set to be rotatable, which can adjust the running trajectory of the plasma on the one hand, and can adjust the etching speed on the other hand.

The movement assembly can be selected among the prior art by a person skilled in the field. Specifically, a rotating shaft can be arranged in the vacuum reaction chamber 110. A push rod that can push the correction grid to rotate along the rotating shaft is arranged at one side of the rotating shaft, wherein the push rod can be an electric or pneumatic telescopic rod. The angle of correction grid 140 is controlled through the control of the length of the telescopic rod. Additionally, the rotating shaft and the push rod can be arranged on one base, wherein the base can move in the vacuum reaction chamber by the turbine and worm or other transmission structures, but it needs to pay attention to maintain the sealing of the vacuum reaction chamber.

As described above, the duration per unit area passing through the uniform area of the ion source reduces with the increase of the distance from the axis of the workpiece disc 120. In order to correct such unevenness introduced by the position, the mesh coverage rates at different positions on the correction grid are different, which can be specifically calculated according to discrete mathematics.

Additionally, it is to be considered that the density of the plasma generated by the plasma excitation source 130 is distributed unevenly due to the effects of the unevenness of the strength of the magnetic field generated by the coil and the diffusion of the etching gas. Generally, such unevenness is reflected in that the plasma concentration is highest at the source center, and reduces along the radial direction of the center. Therefore, the foregoing uniform area of the ion source is in fact a type of approximate evenness. Considering the unevenness of the ion source, the correction grid needs to be “customized” according to the actual situation of the plasma excitation source 130.

During the etching process, it needs to select different gases to adapt to the workpieces made of different materials. Therefore, the plasma excitation source 130 can be provided with a plurality of gas storage tanks 131, and a flow rate of the gas in the gas storage tank 131 is controlled by a gas mass flow controller MFC.

Further, a pressure monitoring device 150 and a vacuum acquiring device 151 are arranged in the vacuum reaction chamber 110.

Preferably, a pressure controller for controlling the opened size of a valve of the vacuum acquiring device 151 according to the pressure monitored by the pressure monitoring device 150 is further provided.

Preferably, the pressure controller is a PID controller.

Preferably, more than four vacuum acquiring devices 151 are provided, and the more than four vacuum acquiring devices 151 are evenly distributed around the plasma excitation source 130.

In order to ensure the vacuum degree in the vacuum reaction chamber 110, the pressure monitoring device 150 and the vacuum acquiring device 151 are provided. When the pressure monitoring device 150 monitors that the pressure in the vacuum reaction chamber 110 is too high, the vacuum acquiring device 151 is turned on. The pressure monitoring device 150 and the vacuum acquiring device 151 in the embodiment only need to satisfy the requirements of the device, and the person skilled in the field can reasonably choose among the prior art.

The opened size of the vacuum acquiring device 151 can be manually controlled by an operator, but considering that the device may need to operate for a long time, a pressure controller is provided for reducing the load of the operator and saving manpower. When the pressure monitored in the vacuum reaction chamber 110 exceeds the preset value, the pressure controller controls the enlargement of the caliber of the vacuum acquiring device 151 to improve the vacuuming rate; and when the pressure monitored in the vacuum reaction chamber 110 is in the range of the preset value, the pressure controller controls the vacuum acquiring device 151 to reduce the caliber. The pressure controller in the embodiment can be selected from the prior art, wherein it only needs to be able to simply determine whether the pressure transmitted by the pressure monitoring device 150 is in the preset range, and the vacuuming rate of the vacuum acquiring device 151 can be improved or reduced according to the determining result. Specifically, the embodiment can adopt the PID controller, which has advantages in control accuracy, response speed, system stability, adaptability, and other aspects. The vacuum acquiring device can be selected from vacuum pumps with suitable specifications.

In order to reduce the disturbance to the gas flow in the reaction chamber when the vacuum acquiring device 151 vacuums, the vacuum acquiring device 151 can be distributed as evenly as possible around the plasma excitation source 130.

Further, a tail gas treatment device 152 is connected to a gas outlet of the vacuum acquiring device 151, wherein a filter is arranged in the tail gas treatment device 152, and an anti-corrosion coating layer is arranged at a position where the filter is in contact with the tail gas.

Preferably, the anti-corrosion coating layer is a polytetrafluoroethylene coating layer.

During the etching process, it needs to select different gases to adapt to the workpieces made of different materials. These gases are extracted from the vacuum reaction chamber 110 by the vacuum acquiring device 151, wherein toxic and harmful gases or tiny particles are formed by a serious of reactions of these gases in the vacuum reaction chamber 110. In order to reduce the pollution to the environment, the tail gas treatment device 152 is provided.

A filter is arranged in the tail gas treatment device 152 for filtering the tiny particles, and the anti-corrosion coating layer is provided for improving the service life of the filter.

Further, a temperature monitoring device 160 and a heat exchanger 161 are arranged in the vacuum reaction chamber 110.

Preferably, a temperature controller for controlling the switching of the heat exchanger 161 according to the temperature monitored by the temperature monitoring device 160 is further provided.

Preferably, the temperature controller is the PID controller.

In order to ensure that the temperature in the vacuum reaction chamber 110 is within the specified range, the temperature monitoring device 160 and the heat exchanger 161 are provided. When the temperature monitoring device 160 monitors that the temperature within the vacuum reaction chamber 110 is too high, the heat exchanger 161 is turned on to cool down; and when the temperature monitoring device 160 monitors that the temperature within the vacuum reaction chamber 110 is too low, the heat exchanger 161 is turned on to heat up. The temperature monitoring device 160 and the heat exchanger 161 in the embodiment only need to satisfy the requirements of the device, and the person skilled in the field can reasonably choose among the prior art. Specifically, the heat exchange device can be a heating rod.

The turning on and turning off of the heat exchanger 161 can be manually controlled by the operator, but considering that the device may need to operate for a long time, the temperature controller is provided for reducing the load of the operator and saving manpower. When the temperature monitored in the vacuum reaction chamber 110 exceeds the preset value, the temperature controller controls the heat exchanger 161 to open the cooling function to reduce the temperature; and when the temperature monitored in the vacuum reaction chamber 110 is the range of the preset value, the temperature controller controls the heat exchanger 161 to turn off or reduce the power. The temperature controller in the embodiment can be selected from the prior art, wherein it only needs to be able to simply determine whether the temperature transmitted by the temperature monitoring device 160 is in the preset range, and can turn on or turn off the heat exchanger 161 or improve the power or reduce the power for the heat exchanger 161 according to the determining result.

Specifically, the PID controller can be used in the embodiment, and it has advantages in control accuracy, response speed, system stability, adaptability, and other aspects.

Further, the plasma excitation source 130 is provided with a mobile assembly that can drive the plasma excitation source 130 to move in X, Y, and Z directions.

The components in contact with the etching gas or the plasma in the plasma excitation source 130 are all made of duplex stainless steel.

The distance between the plasma excitation source 130 and the etching area in a Z-axis direction is between 20˜100 cm.

When performing the etching, since the distance between the plasma excitation source 130 and the workpiece disc 120 needs to be adjusted according to the workpiece situation, the mobile assembly is provided to drive the plasma excitation source 130 to move.

The mobile assembly in the embodiment only needs to drive the plasma excitation source to move in the three-dimensional space. The specific embodiment can be selected from the prior art, and it can refer to the guide rail screw structure. Since a certain vacuum degree needs to be maintained in the vacuum reaction chamber 110, it needs to pay attention to sealing.

Further, the rotating assembly 121 includes a motor and a rotating shaft connected to a power output shaft of the motor, and the workpiece disc 120 is mounted on the rotating shaft.

Preferably, the motor is located in the vacuum reaction chamber 110, wherein the vacuum reaction chamber 110 is provided with an avoidance hole for the rotating shaft to penetrate, and a sealing structure is arranged between the avoidance hole and the rotating shaft.

During the specifical operation, the motor drives the rotating shaft to rotate, so as to drive the workpiece disc 120 to rotate. In order to facilitate the control of the switching of the motor, the motor is arranged outside the vacuum reaction chamber 110. Since a certain vacuum degree needs to be maintained in the vacuum reaction chamber 110, the sealing structure is arranged between the avoidance hole and the rotating shaft.

The sealing structure in the embodiment can be selected from the prior art, e.g., a sealed bearing can be selected.

In order to facilitate the adjustment of the distance between the workpiece disc 120 and the plasma excitation source 130, the workpiece disc 120 can be arranged to be height-adjustable, and specifically an electric telescopic rod can be arranged between the rotating shaft and the workpiece disc 120. Furthermore, a blowing device 170 is further included, wherein the blowing device 170 includes the gas source, the gas pipe connected to the gas source, and the blowing port connected to the gas pipe, wherein the blowing port is arranged towards the workpiece disc 120.

After the etching is finished, the blowing device 170 is turned on to blow the workpiece on the workpiece disc 120, so as to realize the cleaning and cooling for the workpiece.

The blowing area and the etching area of the blowing device 170 can be overlapped or separated, but it needs to avoid the mutual interference between the blowing device 170 and the plasma excitation source 130.

Another embodiment of the present disclosure provides a dry etching method by utilizing the device in the foregoing embodiment, wherein the method includes: placing a substrate to be etched on the workpiece disc 120; driving the workpiece disc 120; charging the etching gas; starting the plasma excitation source 130; performing an etching micro-nano processing on the substrate; and correcting the density of the plasma emitted by the plasma excitation source by adjusting the plasma density correction system before or during the etching.

Further, after starting the plasma excitation source 130, the power of the plasma excitation source is gradually increased to the specified range after the gas pressure and the glow of the plasma are stabilized, so as to perform the etching micro-nano processing for the substrate.

Preferably, before charging the etching gas, the inert gas is first charged to replace the flowing atmosphere in the vacuum reaction chamber, and the inert gas is stopped charging after the replacement is completed.

The pressure of the vacuum reaction chamber 110 is 3×10⁻²˜3×10⁻¹ Pa.

Preferably, the temperature inside the vacuum reaction chamber 110 is 80-120° C.

Preferably, a rotation speed of the workpiece disc 120 is 0˜50 r/min.

Preferably, the blowing device 170 is turned on after the etching is completed, and a flow rate of the blowing gas is 0˜1 (0.01˜1) scm/h.

In the embodiment, the large-sized workpiece is placed on the circle center of the workpiece disc 120. The large-sized workpiece gradually passes through the etching area by different areas by the rotation of the workpiece disc 120, so as to perform the partitioned etching for the large-sized workpiece. Through adjusting the density of the plasma density correction system by the plasma density correction system, the unevenness caused by different durations of the workpieces at different positions passing through the uniform area of the ion source can be reduced.

The above is only the specific embodiment of the present disclosure, but the scope of protection of the disclosure is not limited thereto. Any changes or replacements that can easily be thought of by a person familiar with the technical field within the technical scope disclosed by the present disclosure shall be covered by the protection scope of the present disclosure. Therefore, the scope of protection of the present disclosure shall be governed by the scope of protection of claims.

### Industrial Applicability

The present disclosure provides a dry etching device and a method, wherein the dry etching device includes a vacuum reaction chamber. The vacuum reaction chamber is provided with a workpiece disc driven by a rotating assembly and a plasma excitation source emitting plasma to the etching area, wherein the etching area covers an axis center of the workpiece disc and is located on one side of the axis center, and a plasma density correction system is arranged between the plasma excitation source and the etching area. In the present disclosure, the workpiece rotating into the etching area is etched by utilizing the uniform area of the plasma excitation source. By rotating the workpiece disc when etching, the workpiece rotates around the circle center of the workpiece disc, so that the position on the workpiece sequentially passes through the etching area for etching. The etching area in the embodiment does not need to cover the entire workpiece, and the partitioned etching can be performed on the workpiece by only covering a part of the workpiece. Compared with the traditional dry etching system, it can greatly reduce the volume of the device.

Furthermore, it can be understood that the dry etching device and the method of the present disclosure are reproducible, and can be used in a variety of industrial applications, for example, the dry etching device and the method of the present disclosure can be used in the field of etching.

1. A dry etching device, comprising a vacuum reaction chamber, wherein the vacuum reaction chamber is provided with a workpiece disc driven by a rotating assembly, an etching area, and a plasma excitation source emitting plasma to the etching area, wherein the etching area covers an axis center of the workpiece disc and is located on one side of the axis center, and a plasma density correction system is arranged between the plasma excitation source and the etching area.

2. The dry etching device according to claim 1, wherein the plasma density correction system comprises a correction grid and a movement assembly driving the correction grid to rotate and move;
preferably, a mesh coverage rate of the correction grid gradually reduces in a direction away from an axis of the workpiece disc;
preferably, an angle between the correction grid and the workpiece disc is 0˜75°; and
preferably, the correction grid is made of a metal material or polymer material.

3. The dry etching device according to claim 1, wherein a pressure monitoring device and a vacuum acquiring device are arranged in the vacuum reaction chamber;
preferably, a pressure controller for controlling opened size of a valve of the vacuum acquiring device according to a pressure monitored by the pressure monitoring device is further provided;
preferably, the pressure controller is a PID controller; and
preferably, more than four vacuum acquiring devices are provided, and the more than four vacuum acquiring devices are evenly distributed around the plasma excitation source.

4. The dry etching device according to claim 3, wherein a tail gas treatment device is connected to a gas outlet of the vacuum acquiring device, wherein a filter is arranged in the tail gas treatment device, and an anti-corrosion coating layer is arranged at a position where the filter is in contact with the tail gas; and
preferably, the anti-corrosion coating layer is a polytetrafluoroethylene coating layer.

5. The dry etching device according to claim 1, wherein a temperature monitoring device and a heat exchanger are arranged in the vacuum reaction chamber;
preferably, a temperature controller for controlling switching of the heat exchanger according to a temperature monitored by the temperature monitoring device is further provided; and
preferably, the temperature controller is a PID controller.

6. The dry etching device according to claim 1, wherein the plasma excitation source is provided with a mobile assembly that can drive the plasma excitation source to move in X, Y, and Z directions;
preferably, components in contact with an etching gas or the plasma in the plasma excitation source are all made of duplex stainless steel; and
preferably, a distance between the plasma excitation source and the etching area in a Z-axis direction is between 20˜100 cm.

7. The dry etching device according to claim 1, wherein the rotating assembly comprises a motor, a rotating shaft connected to a power output shaft of the motor, and the workpiece disc is mounted on the rotating shaft; and
preferably, the motor is located in the vacuum reaction chamber, wherein the vacuum reaction chamber is provided with an avoidance hole for the rotating shaft to penetrate, and a sealing structure is arranged between the avoidance hole and the rotating shaft.

8. The dry etching device according to claim 1, further comprising a blowing device, wherein the blowing device comprises a gas source, a gas pipe connected to the gas source, and a blowing port connected to the gas pipe, wherein the blowing port is arranged towards the workpiece disc.

9. A dry etching method by utilizing the device according to claim 1, comprising: placing a substrate to be etched on the workpiece disc; driving the workpiece disc; charging an etching gas; starting the plasma excitation source; performing an etching micro-nano processing on the substrate; and correcting a density of the plasma emitted by the plasma excitation source by adjusting the plasma density correction system before or during etching.

10. The dry etching method according to claim 9, wherein after starting the plasma excitation source, a power of the plasma excitation source is gradually increased to a specified range after a gas pressure and a glow of the plasma are stabilized, so as to perform the etching micro-nano processing for the substrate;
preferably, before charging the etching gas, an inert gas is first charged to replace a flowing atmosphere in the vacuum reaction chamber, and the inert gas is stopped charging after a replacement is completed;
a pressure of the vacuum reaction chamber is 3×10⁻²˜3×10⁻¹ Pa;
preferably, a temperature inside the vacuum reaction chamber is 80-120° C.;
preferably, a rotation speed of the workpiece disc is 0.01˜50 r/min; and
preferably, the blowing device is turned on after the etching is completed, and a flow rate of a blowing gas is 0.01˜1 scm/h.

11. The dry etching method according to claim 9, wherein the plasma density correction system comprises a correction grid and a movement assembly driving the correction grid to rotate and move;
preferably, a mesh coverage rate of the correction grid gradually reduces in a direction away from an axis of the workpiece disc;
preferably, an angle between the correction grid and the workpiece disc is 0˜75°; and
preferably, the correction grid is made of a metal material or polymer material.

12. The dry etching method according to claim 9, wherein a pressure monitoring device and a vacuum acquiring device are arranged in the vacuum reaction chamber;
preferably, a pressure controller for controlling opened size of a valve of the vacuum acquiring device according to a pressure monitored by the pressure monitoring device is further provided;
preferably, the pressure controller is a PID controller; and
preferably, more than four vacuum acquiring devices are provided, and the more than four vacuum acquiring devices are evenly distributed around the plasma excitation source.

13. The dry etching method according to claim 12, wherein a tail gas treatment device is connected to a gas outlet of the vacuum acquiring device, wherein a filter is arranged in the tail gas treatment device, and an anti-corrosion coating layer is arranged at a position where the filter is in contact with the tail gas; and
preferably, the anti-corrosion coating layer is a polytetrafluoroethylene coating layer.

14. The dry etching method according to claim 9, wherein a temperature monitoring device and a heat exchanger are arranged in the vacuum reaction chamber;
preferably, a temperature controller for controlling switching of the heat exchanger according to a temperature monitored by the temperature monitoring device is further provided; and
preferably, the temperature controller is a PID controller.

15. The dry etching method according to claim 9, wherein the plasma excitation source is provided with a mobile assembly that can drive the plasma excitation source to move in X, Y, and Z directions;
preferably, components in contact with an etching gas or the plasma in the plasma excitation source are all made of duplex stainless steel; and
preferably, a distance between the plasma excitation source and the etching area in a Z-axis direction is between 20˜100 cm.

16. The dry etching method according to claim 9, wherein the rotating assembly comprises a motor, a rotating shaft connected to a power output shaft of the motor, and the workpiece disc is mounted on the rotating shaft; and
preferably, the motor is located in the vacuum reaction chamber, wherein the vacuum reaction chamber is provided with an avoidance hole for the rotating shaft to penetrate, and a sealing structure is arranged between the avoidance hole and the rotating shaft.

17. The dry etching method according to claim 9, further comprising a blowing device, wherein the blowing device comprises a gas source, a gas pipe connected to the gas source, and a blowing port connected to the gas pipe, wherein the blowing port is arranged towards the workpiece disc.
